(19) United States
(12) Patent Application Publication
(10) Pub. No.: US 2026/0005494 A1
(43) Pub. Date: Jan. 1, 2026

(54) A SWITCHGEAR CABINET COOLING DEVICE WITH AIR PARTITION AND A CORRESPONDING SWITCHGEAR CABINET ARRANGEMENT

(71) Applicant: RITTAL GMBH & CO. KG, Herborn (DE)

(72) Inventors: Thorsten HEIMBERG, Schöffengrund (DE); Lena Kristin CORNELIUS, Leun (DE); Jörg KNETSCH, Ehringshausen (DE); Juan Carlos CACHO ALONSO, Braunschweig (DE); Lars Walter NIEBERGALL, Wetzlar (DE)

(21) Appl. No.: 18/880,711

(22) PCT Filed: Jul. 10, 2023
(86) PCT No.: PCT/DE2023/100518

§ 371 Date: Jan. 2, 2025

(30) Foreign Application Priority Data
Jul. 12, 2022 (DE) 10 2022 117 360.7

(51) Int. Cl. H02B 1/56; H05K 7/20

(52) U.S. Cl. CPC H02B 1/565; H05K 7/202; H05K 7/20309; H05K 7/20318; H05K 7/20354

(57) ABSTRACT

A cooling device for switchgear cabinet air conditioning which has, in an internal air circuit, an evaporator in the form of an air-liquid heat exchanger, and which has, in an external air circuit which is separated from the internal air circuit via an air partition, a condenser in the form of an air-liquid heat exchanger, wherein the evaporator has a fin pack through which a pipeline system passes, wherein the fin pack projects with at least one of two end sides, on which the pipeline system has at least one pipe bend, through the air partition into the external air circuit, such that the at least one pipe bend is arranged in the external air circuit.

### CROSS-REFERENCE TO RELATED APPLICATIONS

This application is a U.S. National Phase application under 35 U.S.C. 371 of International Application No. PCT/DE2023/100518, filed on Jul. 10, 2023 which claims priority to German Patent Application No. 10 2022 117 360.7, filed on Jul. 12, 2022. The entire disclosures of the above applications are incorporated herein by reference.

### BACKGROUND

This section provides background information related to the present disclosure which is not necessarily prior art.

### TECHNICAL FIELD

The invention is based on a cooling device for switchgear cabinet air conditioning which has, in an internal air circuit, an evaporator in the form of an air-liquid heat exchanger, and which has, in an external air circuit which is separated from the internal air circuit via an air partition, a condenser in the form of an air-liquid heat exchanger. In this case, the evaporator has a fin pack through which a pipeline system passes. A cooling device of this type is described in DE 10 2012 108 110 B4. Further cooling devices are described in DE 10 2010 009 776 A1 and in DE 199 47 970 A1.

### DISCUSSION

Directive 2006/42/EC (Machinery Directive) requires that there is no risk of explosion or fire from gas used in a machine, it being possible to assume that individual components fail. Therefore, if, in the case of a switchgear cabinet cooling device, a refrigerant-carrying part has an assumed leak, it is possible to assume that combustible gas (refrigerant) passes into the switchgear cabinet and can ignite there on internal fittings which ignite arcs during operation. Without a safety function which reliably prevents this, switchgear cabinet cooling devices which use combustible refrigerants cannot meet the machinery directive or be operated with the necessary safety for the end user.

DE 10 2018 109 604 A1 describes a cooling device in which, in the event of a leak in the pipeline system, the internal air circuit of the cooling device is closed at its connection points via which the cooling device is fluidically connected to the interior of a switchgear cabinet housing. The cooling devices known from the prior art have the disadvantage that they are complex to implement since, for example, various actively driven closing members are required and have to be actuated in the event of a detected leak and in the event of entry of a combustible refrigerant into the interior of the switchgear cabinet.

### SUMMARY

This section provides a general summary of the disclosure and is not a comprehensive disclosure of its full scope or all of its features.

It is therefore one aspect of the invention to develop the cooling device described at the outset in such a way that it can be implemented using simple technical means and is accordingly inexpensive to provide.

Accordingly, in a cooling device of the type described at the outset, it is provided that the fin pack projects with at least one of two, preferably opposite, end sides, on which the pipeline system has at least one pipe bend, through the air partition into the external air circuit, so that the at least one pipe bend is arranged in the external air circuit.

The invention is based on the knowledge that the leak-sensitive components of an air-liquid heat exchanger are the pipe bends or their connection points to the rest of the pipeline system, in particular straight, fault-insusceptible pipeline sections. The connection points of the pipe bends can be formed, for example, as joining points, for instance soldered connections, which have an increased leak sensitivity compared to the rest of the pipeline system. If the pipe bends are arranged in the external air circuit of the cooling device, refrigerant evaporating in the event of a leak, in particular combustible refrigerant, for example propane, can be discharged via the external air circuit into the surroundings of the cooling device and in particular kept away from components generating arcs in the interior of a switchgear cabinet housing, to which the cooling device with the internal air circuit could be connected. Air-liquid heat exchangers for switchgear cabinet cooling devices usually have a multiplicity of 180° pipe bends on their opposite end sides, on which straight, parallel pipeline sections are connected to one another in pairs via the bends.

The pipeline system of the fin pack can have, on the pipe bend arranged in the external air circuit, at least one connecting point, preferably a joining point, particularly preferably a soldering point, arranged in the external air circuit.

The pipe bend can be a 180° pipe bend which has, at its opposite ends, in each case one connecting point for a preferably straight pipeline of the pipeline system. The pipe bend can be connected, preferably joined, particularly preferably soldered, to the pipeline in the external air circuit at the connecting point.

The pipeline system, insofar as it is arranged in the internal air circuit, can be free of connecting points, preferably joining points, particularly preferably soldering points. Particularly preferably, the pipeline system, insofar as it is arranged in the internal air circuit, has only straight and preferably mutually parallel pipeline sections. On the end sides, the straight pipeline sections can pass through the air partition. At the passage points, the straight pipeline sections can be sealed with respect to the air partition. The air partition can be provided on the end sides by a fin of the fin pack, for example by an end fin of the fin pack. At the passage points of the straight pipeline sections through the fin, in particular the end fin, the straight pipeline sections can be joined, for instance soldered, in a fluid-tight manner to the fin, in particular to the end fin. The fin or the end fin can be a constituent part of the air partition, in particular in a passage region on the end side of the fin pack, with which the fin pack passes through the air partition.

The fin pack can have a multiplicity of preferably parallel or substantially mutually parallel fins. Of the fins, a fin facing the internal air circuit, for example an end or outer fin, in particular an end fin of the fin pack, can project beyond the fin pack and the at least one pipe bend with a sealing flange. Via the sealing flange, the fin pack can bear sealingly against the (remaining) air partition. The fin facing the internal air circuit, for example an end or outer fin, in particular an end fin of the fin pack and/or at least the sealing flange can be a constituent part of the air partition.

In this case, the fin facing furthest towards the external air circuit can be an end fin of the fin pack, via which the evaporator is mounted in a fluidically sealed manner in the cooling device, preferably on the air partition. For this purpose, the fin, in particular the end fin, can have a sealing flange, preferably a circumferential sealing flange, in particular a sealing flange, which extends around the entire circumference of the fin, in particular of the end fin.

The end fin can be an external fin of the fin pack. The fin pack can have in each case one end fin on the two opposite end sides of the evaporator. The end sides can be formed by the end fins. The end fins can be passed through by the pipeline system of the evaporator. The pipeline system can extend with the pipe bends beyond the end sides or the end fins. The pipeline system can be arranged with the pipe bends and preferably exclusively with the pipe bends outside the fin pack.

An end fin, for example an end fin, of the fin pack can be the air partition or at least one constituent part of the air partition. The end fin of the fin pack, for example an end fin, can have a sealing flange, for example an offset, which bears fluidically sealingly against the air partition.

The evaporator can be accommodated in a housing of the air partition, which housing is open in the air passage direction of the evaporator, wherein the evaporator bears sealingly against the housing via the sealing flange, preferably on the inner circumference of an aperture of the housing.

The sealing flange can be a circumferentially closed sealing flange of an end fin of the fin pack, preferably a rectangular sealing frame. To increase the stability and sealing action, the end fin can have an increased strength compared to the remaining fins of the fin pack, for example a greater material thickness, in particular a greater sheet thickness.

The sealing flange can bear sealingly against a border of the aperture in an aperture of the air partition, such that the aperture is preferably closed completely by the end fin.

The evaporator, the condenser and the pipeline system can be constituent parts of a refrigerating machine. The refrigerating machines can furthermore have a compressor and an expansion member. All constituent parts of the refrigerating machines can be arranged completely in the external air circuit, except for a central region of the fin pack of the evaporator, which central region is arranged in the internal air circuit and through which air flows.

The fin pack can have, on its end side, with which it projects through the air partition into the external air circuit, a condensate discharge in the external air circuit for condensate accumulating on the at least one pipe bend.

A switchgear cabinet arrangement has, in addition to at least one cooling device of the type described above, a switchgear cabinet housing, on which the cooling device is mounted. In this case, air is transported from an interior of the switchgear cabinet housing through the internal air circuit of the cooling device, wherein ambient air of the switchgear cabinet arrangement is transported through the external air circuit.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

Further details of the invention will be explained with reference to the figures below. In the figures:

FIG. 1 shows a schematic illustration of a switchgear cabinet arrangement according to the prior art;

FIG. 2 shows a schematic illustration of a comparison of the arrangement of an evaporator in a cooling device according to the prior art and in a manner according to the invention; and

FIG. 3 shows an exploded illustration of an exemplary embodiment of an evaporator with end fins on the opposite end sides.

### DETAILED DESCRIPTION

Example embodiments will now be described more fully with reference to the accompanying drawings.

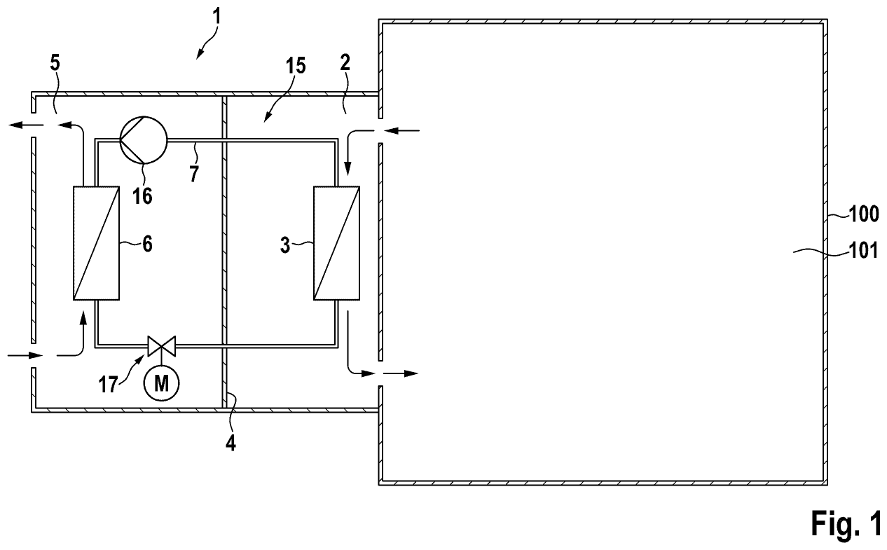

FIG. 1 shows a switchgear cabinet arrangement with a cooling device 1 and a switchgear cabinet housing 100, on which the cooling device 1 is mounted. The cooling device 1 has an internal air circuit 2 and an external air circuit 5. The air accommodated in the interior 101 of the switchgear cabinet housing 100 is introduced into the internal air circuit 2 in an upper region of the cooling device, conducted through the evaporator 3 and conducted back into the interior 101 as cooled air in a lower region of the switchgear cabinet 100. Switchgear cabinet components (not illustrated), which can generate arcs during operation, for example electrical switching devices, can be arranged in the interior 101 of the switchgear cabinet housing 100. Accordingly, if the pipeline system 7 were to enter a combustible refrigerant into the atmosphere in the interior 101 of the switchgear cabinet housing 100 in the event of a leak, the air-gas mixture could ignite on the arc. The switchgear cabinet arrangement shown in FIG. 1 can therefore be operated only with noncombustible refrigerant according to the machinery directive.

The pipeline system 7 is constituent parts of a refrigerating machine 15 which, in addition to the evaporator 3 in the internal circuit 2 and the condenser 6 in the external circuit 5, furthermore has a compressor 16 and an expansion member 17. In a lower region of the cooling device 1, ambient air is sucked into the internal air circuit 2, conducted through the condenser 6 and blown out of the external air circuit 5 into the surroundings of the switchgear cabinet arrangement 100 in an upper region of the cooling device 1. For the transport of the air through the external air circuit 5 on the one hand and the internal air circuit 2 on the other hand, in each case one fan (not illustrated) is arranged in the respective air circuit 2, 5. In the case of the external air circuit 5, the fan can be in the form of a filter fan.

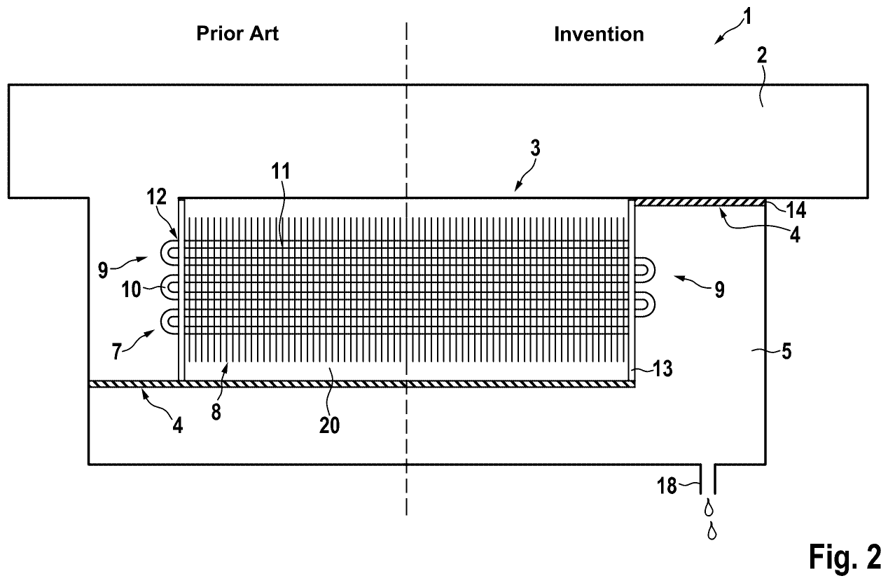

In order to avoid the entry of evaporating combustible refrigerant into the internal air circuit 2 in the event of a leak of the pipeline system 7, in the solution according to the invention, as shown by way of example in FIG. 2, it is provided that the fin pack 8 projects with at least one of two opposite end sides, preferably with both end sides 9, on which the pipeline system 7 has at least one pipe bend 10, through the air partition 4 into the external air circuit 5, so that the at least one pipe bend 10 is arranged in the external air circuit 5. The invention is based on the knowledge that the leakage of the pipeline system 7 takes place in particular in the region of the pipe bends 10 or the connecting points 12 of the pipe bends 10 to the straight line sections 11. If, consequently, these particularly critical regions are arranged outside the internal air circuit 2, consequently in the external air circuit 5, the risk of the entry of evaporating refrigerant into the internal air circuit 2 can be reduced effectively to virtually zero.

The fin pack 8 has a multiplicity of preferably parallel fins 13, of which the end fin 13, facing the internal air circuit 2, of the fin pack 8 projects beyond the fin pack 8 and the pipe bends 10 on the relevant end side. In particular, the evaporator 3 is mounted in a fluidically sealed manner via the end fin 13 in the cooling device 1, namely on the air partition 4. Consequently, with the exception of a central region of the evaporator 3, in which only straight pipe sections 11 extend parallel to one another, which are not very susceptible to leakage, the entire refrigerant circuit is arranged in the external air circuit 5, so that refrigerant escaping in the event of a leak can be discharged from the internal circuit 2 into the surroundings of the cooling device 1 in a sealed manner. Condensate accumulating on the pipe bends 10 in the external air circuit 5 is discharged from the external air circuit via a condensate discharge 18.

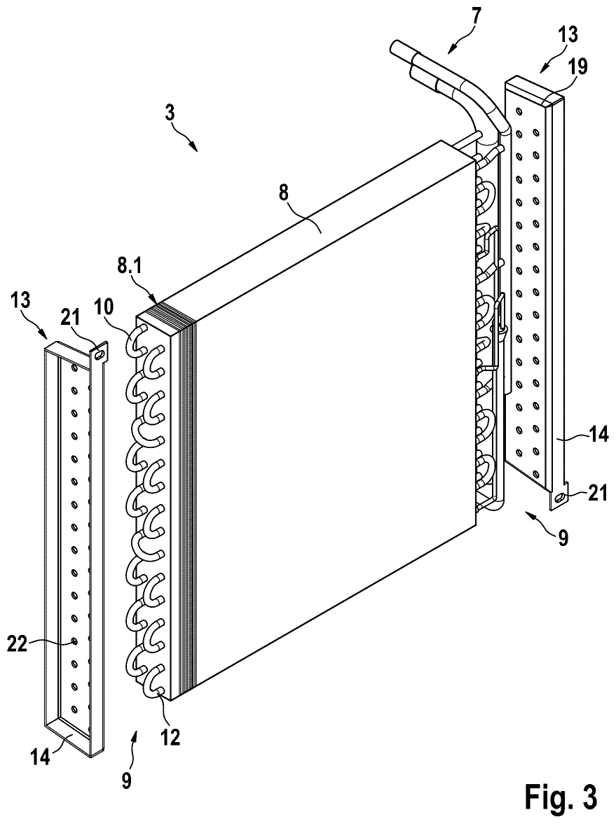

FIG. 3 shows an exemplary embodiment of an evaporator 3, wherein the end fins 13 are shown in an exploded illustration for better clarity. The evaporator 3 is in the form of an air-liquid heat exchanger which has a fin pack 8 with a multiplicity of parallel fins 8.1. The fins 8.1 of the fin pack 8 are passed through perpendicularly to the opposite end sides 9 of the evaporator 3 by a pipeline system 7 composed of a multiplicity of parallel pipeline sections. The pipeline system 7 projects with pipe bends 10 on the opposite end sides 9 out of the fin pack 8. On the opposite end sides 9, in particular outside the fin pack 8, the pipe bends 10 are connected to the parallel pipeline sections via connecting points 12, for example soldering points. The connecting points are susceptible to leakage and should therefore be arranged outside the internal air circuit in which the fin pack 8 is located, in particular in the external air circuit, so that combustible refrigerant escaping in the event of a leak cannot enter through the internal air circuit of the cooling device into the switchgear cabinet interior, where it can ignite on electrical internal fittings of the switchgear cabinet which can generate arcs.

The illustrated end fins 13 should accordingly be arranged directly on the end sides 9 of the evaporator 3 and passed through by the pipeline system 7. For this purpose, the end fins 13 have passages 22. In particular, the pipeline system 7 can thus be separated at least in the circumference of the pipe bends 10, including the joining points 12, by the end fins from the further constituent parts of the evaporator 3, in particular from the fins 8.1 of the fin pack 8. Thus, it is possible, for example, for the end fins 13 to be arranged with the circumferential sealing flange 14 in an aperture of an air partition of the switchgear cabinet cooling device, wherein the air partition separates the internal air circuit from the external air circuit of the cooling device. If at least the fin pack 8 is arranged in the internal air circuit, the connecting points 12 susceptible to leakage can be arranged in the external air circuit through the aperture of the air partition, while the fluidic separation of internal air circuit and external air circuit is maintained via the sealing flange 14. The end fin 13 then forms a constituent part of the air partition.

The end fins 13 can be formed, for example, as sheet metal parts. However, the end fins 13 can also be formed as plastic parts. The end fins can have a strength, for example a sheet thickness, which is sufficient to ensure a sufficient sealing action of the sealing flanges 14. For example, the fins 8.1 of the fin pack 8 can be formed from thin sheet metal. By contrast, the end fin 13 can have a greater sheet thickness. The sealing flange 14 can have at least one fastening tab 21 in order to arrange the evaporator 3, for example fluidically sealingly, in an aperture of an air partition between the internal air circuit and the external air circuit.

The features of the invention disclosed in the above description, in the drawing and in the claims can be essential both individually and in any desired combination for the realization of the invention.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1-15. (canceled)

16. A switchgear cabinet cooling device comprising an internal air circuit, an evaporator in the form of an air-liquid heat exchanger, and which has, in an external air circuit which is separated from the internal air circuit via an air partition, a condenser in the form of an air-liquid heat exchanger, wherein the evaporator has a fin pack through which a pipeline system passes, wherein the fin pack projects with at least one of two end sides, on which the pipeline system has at least one pipe bend, through the air partition into the external air circuit, such that the at least one pipe bend is arranged in the external air circuit.

17. The switchgear cabinet cooling device according to claim 16, in which the pipeline system of the fin pack has, on the pipe bend arranged in the external air circuit, at least one connecting point, preferably a joining point, particularly preferably a soldering point, arranged in the external air circuit.

18. The switchgear cabinet cooling device according to claim 16, in which the pipe bend is a 180° pipe bend which has, at its opposite ends, in each case one connecting point for a preferably straight pipeline of the pipeline system, wherein the pipe bend is connected, preferably joined, particularly preferably soldered, to the pipeline in the external air circuit at the connecting point.

19. The switchgear cabinet cooling device according to claim 16, in which the pipeline system, insofar as it is arranged in the internal air circuit, is free of connecting points, preferably joining points, particularly preferably soldering points.

20. The switchgear cabinet cooling device according to claim 16, in which the pipeline system, insofar as it is arranged in the internal air circuit, has exclusively straight and preferably mutually parallel pipeline sections.

21. The switchgear cabinet cooling device according to claim 16, in which the fin pack has a multiplicity of preferably parallel or substantially mutually parallel fins, of which one fin facing the external air circuit, preferably an end fin of the fin pack, projects beyond the fin pack and the at least one pipe bend with a sealing flange, via which the fin pack bears sealingly against the air partition.

22. The switchgear cabinet cooling device according to claim 21, in which the fin facing the internal air circuit is an end fin of the fin pack, via which the evaporator is mounted in a fluidically sealed manner in the switchgear cabinet cooling device, preferably on the air partition.

23. The switchgear cabinet cooling device according to claim 16, in which an end fin, preferably an end fin, of the fin pack is the air partition or is at least one constituent part of the air partition.

24. The switchgear cabinet cooling device according to claim 16, in which an end fin of the fin pack has a sealing flange, for example an offset, which bears sealingly against the air partition.

25. The switchgear cabinet cooling device according to claim 24, in which the evaporator is accommodated in a housing of the air partition, which housing is open in the air passage direction of the evaporator, wherein the evaporator bears sealingly against the housing via the sealing flange.

26. The switchgear cabinet cooling device according to claim 24, in which the sealing flange is a circumferentially closed sealing flange of the end fin, preferably a rectangular sealing frame.

27. The switchgear cabinet cooling device according to claim 24, in which the sealing flange bears sealingly against a border of the aperture in an aperture of the air partition, such that the aperture is closed by the end fin.

28. The switchgear cabinet cooling device according to claim 16, in which the evaporator, the condenser and the pipeline system are constituent parts of a refrigerating machine with a compressor and an expansion member, which refrigerating machine is arranged completely in the external air circuit, except for a central region of the fin pack of the evaporator, which central region is arranged in the internal air circuit and through which air flows.

29. The switchgear cabinet cooling device according to claim 16, in which the fin pack has, on its end side, with which it projects through the air partition into the external air circuit, a condensate discharge in the external air circuit for condensate accumulating on the at least one pipe bend.

30. A switchgear cabinet arrangement with a switchgear cabinet cooling device according to claim 16 and a switchgear cabinet housing, on which the switchgear cabinet cooling device is mounted, wherein air is transported from an interior of the switchgear cabinet housing through the internal air circuit, and wherein ambient air of the switchgear cabinet arrangement is transported through the external air circuit.
